(19) United States
(12) Patent Application Publication
(10) Pub. No.: US 2025/0133697 A1
(43) Pub. Date: Apr. 24, 2025

(54) Cooling System Assembly

(71) Applicant: Cooler Master Co., Ltd., Taipei City (TW)

(72) Inventors: Fuming Zhong, Taipei City (TW); Shiping Luo, Taipei City (TW)

(21) Appl. No.: 18/909,099

(22) Filed: Oct. 8, 2024

(30) Foreign Application Priority Data
Oct. 23, 2023 (CN) 202311378418.1

(51) Int. Cl. H05K 7/20; F28D 15/04

(52) U.S. Cl. CPC H05K 7/20336; H05K 7/20409; F28D 15/046

(57) ABSTRACT

A cooling system assembly may include a three-dimensional heat exchanger and liquid cooling unit. The three-dimensional heat exchanger includes a vapor chamber having a first thermally conductive plate and second thermally conductive plate, together, forming a liquid-tight chamber. The liquid-tight chamber includes a first sub-chamber and second sub-chamber encircling the first sub-chamber. The first thermally conductive plate includes a first thermal transfer surface configured to couple to a packaged integrated circuit on an opposite side of the first sub-chamber. The liquid cooling unit includes at least one coolant-carrying channel thermally coupled to an outside surface of the second sub-chamber. When coupled to the at least one packaged integrated circuit, the three-dimensional heat exchanger transports heat away from the at least one packaged integrated circuit and the liquid cooling unit transports heat away from the three-dimensional heat exchanger.

### RELATED APPLICATIONS

This US application claims the benefit of priority to China application no. 202311378418.1, filed on Oct. 23, 2023, of which is incorporated herein by reference in its entirety.

### TECHNICAL FIELD

The present disclosure relates to heat-transfer components and assemblies, and more particularly, but not limited to, three-dimensional heat exchanger assemblies.

### BACKGROUND OF THE INVENTION

With increasing processing speed and performance of electronic devices, the amount of heat generated during operation of an electronic device has increased. The heat generation increases the temperature of the electronic device and, if the heat cannot be dissipated effectively, the reliability and performance of the electronic device is reduced. To prevent overheating of an electronic device, cooling systems such as air-cooling systems and liquid cooling systems are used to efficiently dissipate the heat generated by the electronic device and, thereby ensure the standard operation of the electronic device.

In the case of air-cooling systems for packaged integrated circuits, heat is dissipated from an upper surface of a packaged integrated circuit via upper surface adherence of a heatsink or vapor chamber to the packaged integrated circuit. The heatsink or vapor chamber is commonly mounted to the packaged integrated circuits via attachment members such as screws and push pins. Notwithstanding however, increasing thermal conductivity of air-cooling systems continue to be challenging.

### SUMMARY OF THE INVENTION

The present disclosure provides a cooling system assembly with higher thermal conductivity.

In some aspects, the techniques described herein relate to a cooling system assembly, including a three-dimensional heat exchanger and a liquid cooling unit. The three-dimensional heat exchanger is configured for phase-change of a first cooling fluid. The three-dimensional heat exchanger includes a vapor chamber having a first thermally conductive plate and a second thermally conductive plate. The first thermally conductive plate and the second thermally conductive plate together form a liquid-tight chamber. The liquid-tight chamber includes a first sub-chamber and a second sub-chamber fluidly coupled to the first sub-chamber. The second sub-chamber encircles the first sub-chamber. The first thermally conductive plate includes a first thermal transfer surface. The first thermal transfer surface is on one side and the first sub-chamber on an opposite side of the first thermal transfer surface. The first thermal transfer surface is configured to thermally couple to at least one packaged integrated circuit. The liquid cooling unit is configured to be flow through by a second cooling fluid. The liquid cooling unit includes at least one coolant-carrying channel. The at least one coolant-carrying channel is coupled to an outside surface of the second sub-chamber. When the first thermal transfer surface is thermally coupled to the at least one packaged integrated circuit, the three-dimensional heat exchanger transports heat away from the at least one packaged integrated circuit and the liquid cooling unit transports heat away from the three-dimensional heat exchanger. In some aspects, the techniques described herein relate to a cooling system assembly, wherein the first sub-chamber includes a first thickness and the second sub-chamber includes a second thickness, the first thickness greater than the second thickness. In some aspects, the techniques described herein relate to a cooling system assembly, wherein a material of the vapor chamber is selected from a group consisting of an aluminum, aluminum-alloy, copper, and copper-alloy material.

In some aspects, the techniques described herein relate to a cooling system assembly, wherein the three-dimensional heat exchanger further includes a fin stack and a plurality of heat pipes, and the second thermally conductive plate includes a plurality of thermal transfer through holes. Each plurality of heat pipes respectfully include an open end and a closed end. Each plurality of heat pipes is respectively thermally coupled to the fin stack and the open end of each plurality of heat pipes is respectively fluidly coupled to the vapor chamber through each plurality of thermal transfer through holes. In some aspects, the techniques described herein relate to a cooling system assembly, wherein the plurality of thermal transfer through holes is disposed fluidly coupled to the second sub-chamber. In some aspects, the techniques described herein relate to a cooling system assembly, wherein the plurality of heat pipes includes twenty-eight plurality of heat pipes.

In some aspects, the techniques described herein relate to a cooling system assembly, wherein the at least one coolant-carrying channel includes at least one heat pipe. In some aspects, the techniques described herein relate to a cooling system assembly, wherein the at least one coolant-carrying channel includes an inlet and an outlet, whereby the second cooling fluid flows through the at least one coolant-carrying channel via the inlet and the outlet.

In some aspects, the techniques described herein relate to a cooling system assembly, further including a plurality of support pillars. The plurality of support pillars includes a plurality of first support pillars and a plurality of second support pillars. Each plurality of support pillars is thermally coupled to the first thermally conductive plate and the second thermally conductive plate. The plurality of first support pillars is disposed in the first sub-chamber and the plurality of second support pillars is disposed in the second sub-chamber.

In some aspects, the techniques described herein relate to a cooling system assembly, further including a plurality of capillary structures. The plurality of capillary structures include a plurality of first capillary structures and a plurality of second capillary structures. Each plurality of first capillary structures is coupled to and surround each plurality of first support pillars. Each plurality of second capillary structures is thermally coupled to and surround at least one plurality of second support pillars. In some aspects, the techniques described herein relate to a cooling system assembly, wherein the plurality of capillary structures consist of a sintered powder structure. In some aspects, the techniques described herein relate to a cooling system assembly, further including capillary structures covering surfaces of the liquid-tight chamber. In some aspects, the techniques described herein relate to a cooling system assembly, wherein the capillary structures consist of a sintered powder structure.

In some aspects, the techniques described herein relate to a cooling system assembly, wherein the first thermally conductive plate further includes a second thermal transfer surface. The second thermal transfer surface encircles the first thermal transfer surface. The second thermal transfer surface is opposite the second sub-chamber. The at least one coolant-carrying channel is thermally coupled to the second thermal transfer surface.

In some aspects, the techniques described herein relate to a cooling system assembly, wherein the at least one coolant-carrying channel includes a first thermal transfer channel surface. The first thermal transfer channel surface is substantially flat and the first thermal transfer channel surface thermally coupled to the second thermal transfer surface.

In some aspects, the techniques described herein relate to a cooling system assembly, wherein the first thermally conductive plate further includes a channel groove, and the at least one coolant-carrying channel includes a second thermal transfer channel surface. The second thermal transfer channel surface is substantially curved and the second thermal transfer channel surface is thermally coupled to the channel groove. A plane of the second thermal transfer surface and the first thermal transfer channel surface is substantially flat.

In some aspects, the techniques described herein relate to a cooling system assembly, wherein the at least one coolant-carrying channel includes a third thermal transfer channel surface and a fourth thermal transfer channel surface. The third thermal transfer channel surface and the fourth thermal transfer channel surface being substantially flat. The fourth thermal transfer channel surface is opposite the third thermal transfer channel surface. The third thermal transfer channel surface is thermally coupled to the second thermal transfer surface.

In some aspects, the techniques described herein relate to a cooling system assembly, wherein the second thermally conductive plate further includes a third thermal transfer surface. The third thermal transfer surface is opposite the second sub-chamber. The at least one coolant-carrying channel is thermally coupled to the third thermal transfer surface. In some aspects, the techniques described herein relate to a cooling system assembly, wherein the fourth thermal transfer channel surface is thermally coupled to the third thermal transfer surface.

### BRIEF DESCRIPTION OF DRAWINGS

Unless specified otherwise, the accompanying drawings illustrate aspects of the innovative subject matter described herein. Referring to the drawings, wherein like reference numerals indicate similar parts throughout the several views, several examples of three-dimensional heat exchangers and liquid cooling units incorporating aspects of the presently disclosed principles are illustrated by way of example, and not by way of limitation.

FIG. 1A illustrates a perspective view of a cooling system assembly, in accordance with various embodiments of the present disclosure.

FIG. 1B illustrates an exploded view of the cooling system assembly of FIG. 1A, in accordance with various embodiments of the present disclosure.

FIG. 2 illustrates a partial cross-sectional view of the cooling system assembly of FIG. 1A, in accordance with various embodiments of the present disclosure.

FIG. 3 illustrates a perspective view of an alternative cooling system assembly, in accordance with various embodiments of the present disclosure.

FIG. 4 illustrates a partial cross-sectional view of the alternative cooling system assembly of FIG. 3, in accordance with various embodiments of the present disclosure.

FIG. 5 illustrates a perspective view of another alternative cooling system assembly, in accordance with various embodiments of the present disclosure.

FIG. 6 illustrates a partial cross-sectional view of the another alternative cooling system assembly of FIG. 5, in accordance with various embodiments of the present disclosure.

FIG. 7 illustrates a perspective view of yet another alternative cooling system assembly, in accordance with various embodiments of the present disclosure.

FIG. 8 illustrates a partial cross-sectional view of the yet another alternative cooling system assembly of FIG. 7, in accordance with various embodiments of the present disclosure.

### DETAILED DESCRIPTION

The following describes various principles related to components and assemblies for electronic devices cooling by way of reference to specific examples of cooling system assemblies, including specific arrangements and examples of three-dimensional heat exchangers and liquid cooling units embodying innovative concepts. More particularly, but not exclusively, such innovative principles are described in relation to selected examples of thermal transfer surfaces of vapor chambers and coolant-carrying channels coupled to the thermal transfer surfaces of vapor chambers, and well-known functions or constructions are not described in detail for purposes of succinctness and clarity. Nonetheless, one or more of the disclosed principles can be incorporated in various other embodiments of thermal transfer surfaces of vapor chambers and coolant-carrying channels coupled to the thermal transfer surfaces of vapor chambers to achieve any of a variety of desired outcomes, characteristics, and/or performance criteria.

Thus, thermal transfer surfaces of vapor chambers and coolant-carrying channels coupled to the thermal transfer surfaces of vapor chambers having attributes that are different from those specific examples discussed herein can embody one or more of the innovative principles, and can be used in applications not described herein in detail. Accordingly, embodiments of thermal transfer surfaces of vapor chambers and coolant-carrying channels coupled to the thermal transfer surfaces of vapor chambers not described herein in detail also fall within the scope of this disclosure, as will be appreciated by those of ordinary skill in the relevant art following a review of this disclosure.

Example embodiments as disclosed herein are directed to cooling system assemblies that can be used in cooling systems to dissipate high heat loads. The cooling system may be configured on a chassis, within a chassis, or as part of an electronics system that includes heat producing electronic components to be cooled. The cooling system includes at least one three-dimensional heat exchanger and at least one liquid cooling unit. The three-dimensional heat exchangers may be thermally coupled to an upper surface of a packaged integrated circuit, absorbing heat from the packaged integrated circuit and transporting the heat away via heat pipes coupled to a fin stack. The at least one liquid cooling unit includes one or more liquid-based cooling loops. The liquid-based cooling loops may include coolant-carrying channels such as heat pipes. The coolant-carrying channels may be thermally coupled to the three-dimensional heat exchangers, absorbing heat from the three-dimensional heat exchangers and transporting the heat away via cooling lines (tubing or piping) coupled to fin stacks (or radiators). One or more pumps may drive cooling fluid through the liquid-based cooling loops. Heat may be transported to an air plenum or to an outside of a chassis or electronics system via the fin stack and the coolant-carrying channels, naturally or forced (e.g. one or more fans coupled to a back end of fin stacks via fasteners such as bolts, screws, etc.). The integrated circuit may include central processing units (CPUs), graphics processing units (GPUs), etc.

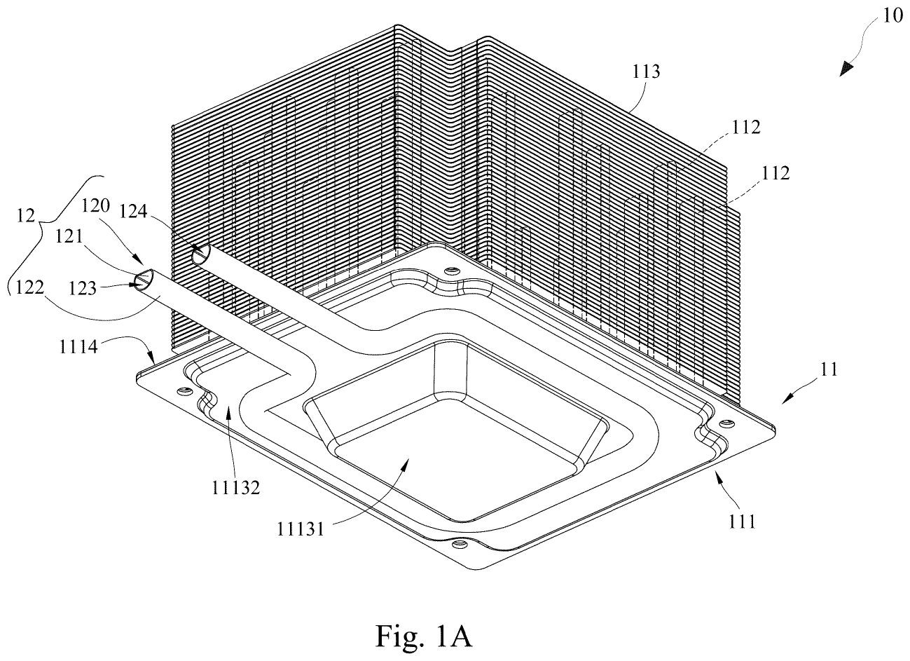

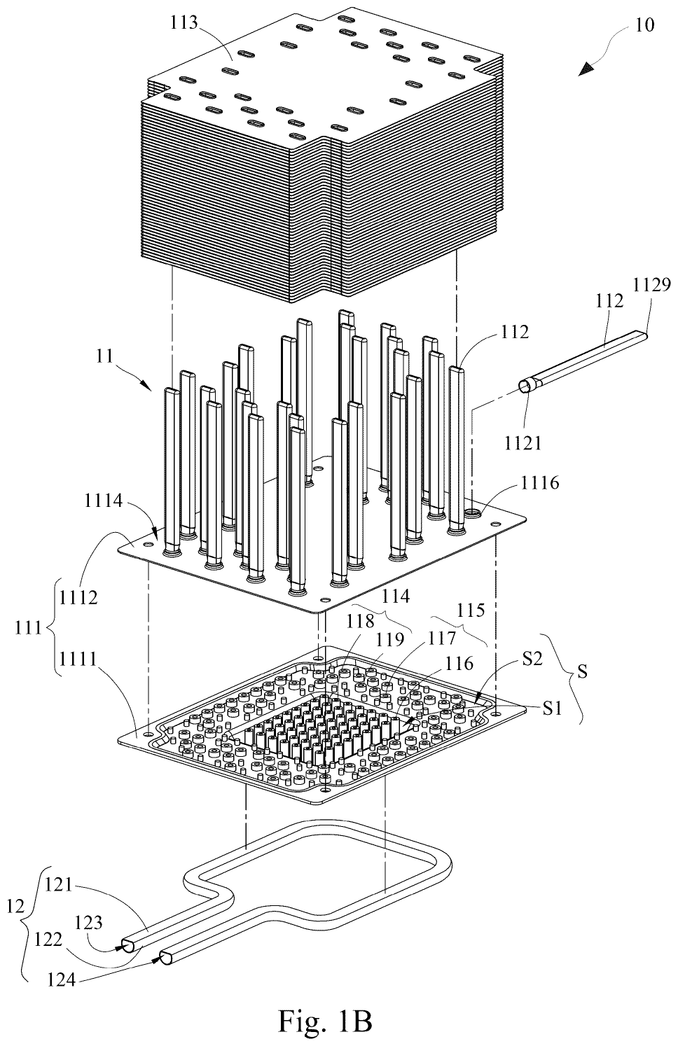

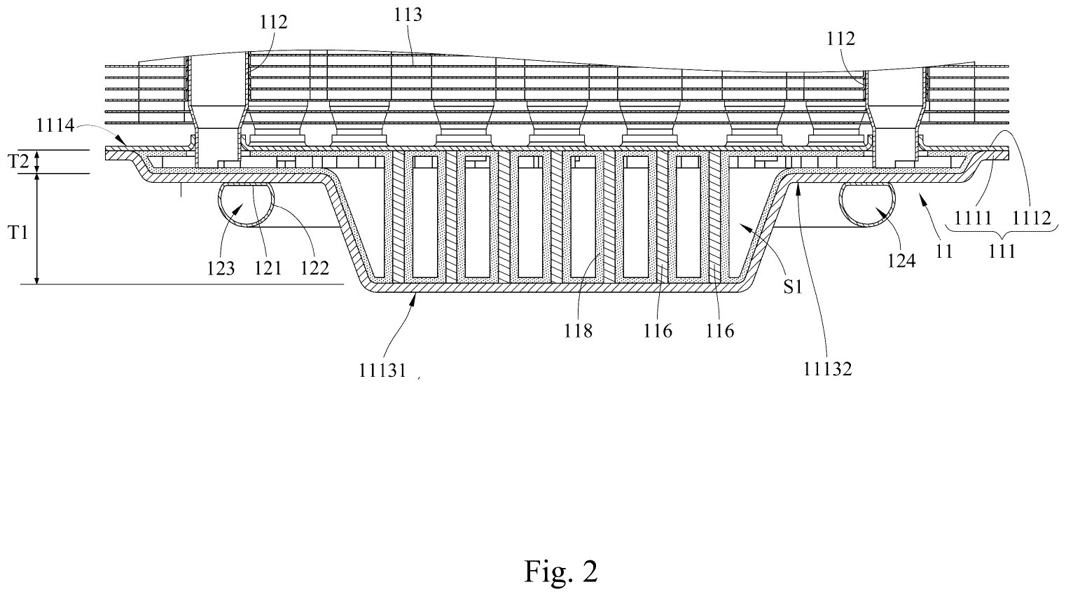

FIGS. 1A to 2 illustrate a cooling system assembly 10, in accordance with various embodiments of the present disclosure. The cooling system assembly 10 includes a three-dimensional heat exchanger 11, 11A and a liquid cooling unit 12. The three-dimensional heat exchanger 11 is configured for phase-change of a first cooling fluid (not shown). The three-dimensional heat exchanger 11 includes a vapor chamber 111 having a first thermally conductive plate 1111 and a second thermally conductive plate 1112. The first thermally conductive plate 1111 and the second thermally conductive plate 1112 together form a liquid-tight chamber S. The liquid-tight chamber S includes a first sub-chamber S1 and a second sub-chamber S2 fluidly coupled to the first sub-chamber S1. The second sub-chamber S2 encircles the first sub-chamber S1. The first thermally conductive plate 1111 includes a first thermal transfer surface 11131. The first thermal transfer surface 11131 is on one side and the first sub-chamber S1 on an opposite side of the first thermal transfer surface 11131. The first thermal transfer surface 11131 is configured to thermally couple to at least one packaged integrated circuit (not shown). The liquid cooling unit 12 is configured to be flow through by a second cooling fluid (not shown). The liquid cooling unit 12 includes at least one coolant-carrying channel 120. The at least one coolant-carrying channel 120 is coupled to an outside surface of the second sub-chamber S2. When the first thermal transfer surface 11131 is thermally coupled to the at least one packaged integrated circuit, the three-dimensional heat exchanger 11 transports heat away from the at least one packaged integrated circuit and the liquid cooling unit 12 transports heat away from the three-dimensional heat exchanger 11. In some embodiments, the first sub-chamber S1 includes a first thickness T1 and the second sub-chamber S2 includes a second thickness T2, the first thickness T1 greater than the second thickness T2.

In some embodiments, the three-dimensional heat exchanger 11 further includes a fin stack 113 and a plurality of heat pipes 112, and the second thermally conductive plate 1112 includes a plurality of thermal transfer through holes 1116. Each plurality of heat pipes 112 respectfully include an open end 1121 and a closed end 1129. Each plurality of heat pipes 112 is respectively thermally coupled to the fin stack 113 and the open end 1121 of each plurality of heat pipes 112 is respectively fluidly coupled to the vapor chamber 111 through each plurality of thermal transfer through holes 1116. In some embodiments, the plurality of thermal transfer through holes 1116 is disposed fluidly coupled to the second sub-chamber S2. In some embodiments, the plurality of heat pipes 112 includes twenty-eight plurality of heat pipes 112. In some embodiments, the plurality of heat pipes 112 includes less than twenty-eight plurality of heat pipes 112.

In some embodiments, the first thermally conductive plate 1111 further includes a second thermal transfer surface 11132. The second thermal transfer surface 11132 encircles the first thermal transfer surface 11131. The second thermal transfer surface 11132 is opposite the second sub-chamber S2. The at least one coolant-carrying channel 120 is thermally coupled to the second thermal transfer surface 11132. In some embodiments, the at least one coolant-carrying channel 120 includes a first thermal transfer channel surface 121. The first thermal transfer channel surface 121 is substantially flat and the first thermal transfer channel surface 121 is thermally coupled to the second thermal transfer surface 11132.

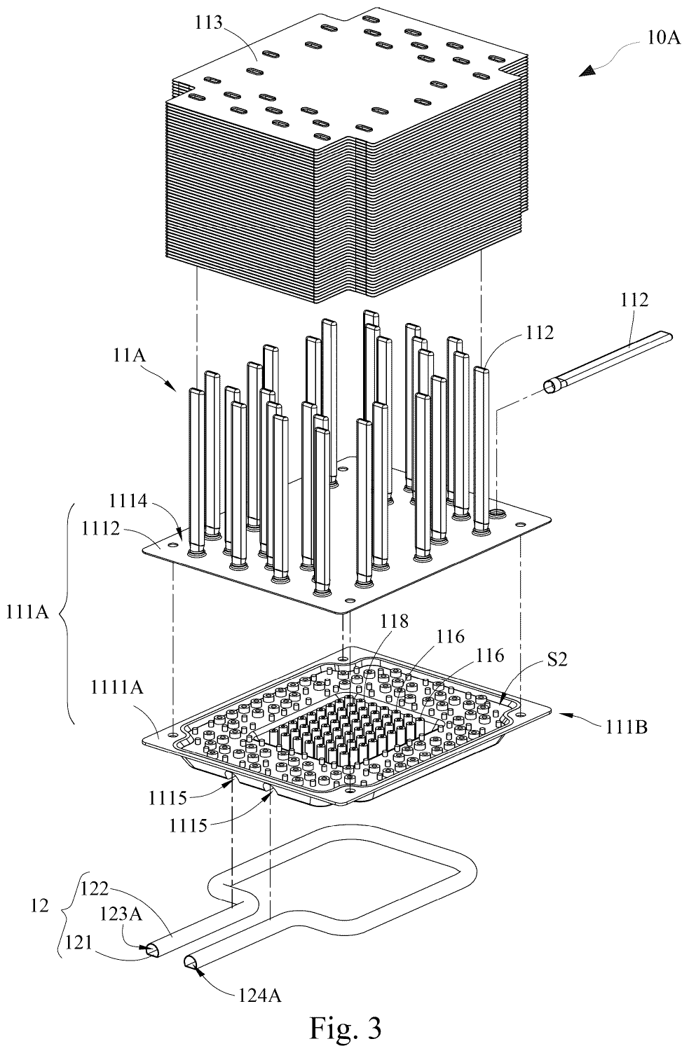

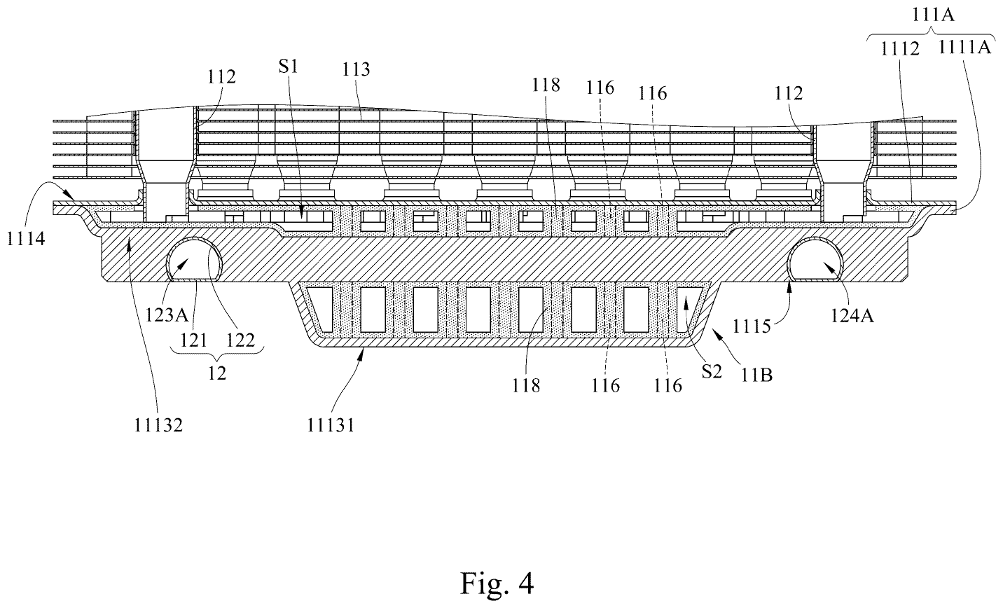

FIGS. 3 to 4 illustrate an alternative cooling system assembly 10A, in accordance with various embodiments of the present disclosure. The alternative cooling system assembly 10A may be similar in some respects to the cooling system assembly 10 of FIGS. 1A to 2, and therefore may be best understood with reference thereto where like numerals designate like components not described again in detail. The cooling system assembly 10A includes a three-dimensional heat exchanger 11A and the liquid cooling unit 12. The three-dimensional heat exchanger 11A includes a vapor chamber 111A having a first thermally conductive plate 1111A and a second thermally conductive plate 1112. In some embodiments, the first thermally conductive plate 1111A further includes a channel groove 1115, and the at least one coolant-carrying channel 120 includes a second thermal transfer channel surface 122. The second thermal transfer channel surface 122 is substantially curved and the second thermal transfer channel surface 122 is thermally coupled to the channel groove 1115. A plane of the second thermal transfer surface 11132 and the first thermal transfer channel surface 121 is substantially flat. In some embodiments, as an example, the substantially flat first thermal transfer channel surface 121 and the substantially curved second thermal transfer channel surface 122 are formed by stamping. In some embodiments, a material of the vapor chamber 111, 111A is selected from a group consisting of a thermally conductive metal. In some embodiments, a material of the vapor chamber 111, 111A is selected from a group consisting of an aluminum, aluminum-alloy, copper, and copper-alloy material.

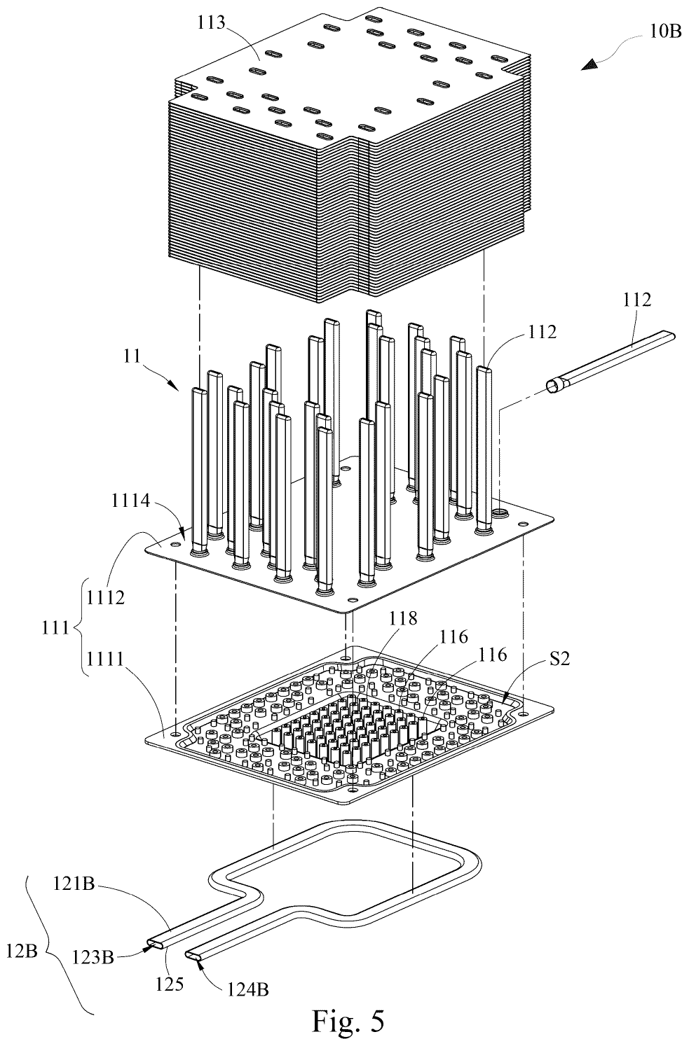

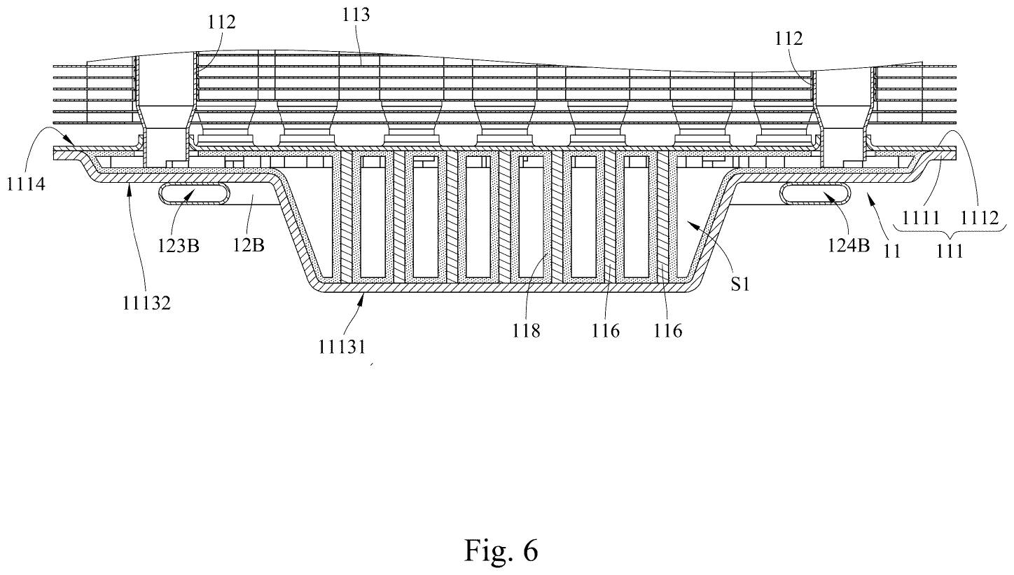

FIGS. 5 to 6 illustrate another alternative cooling system assembly 10B, in accordance with various embodiments of the present disclosure. The another alternative cooling system assembly 10B may be similar in some respects to the cooling system assembly 10 of FIGS. 1A to 2, and therefore may be best understood with reference thereto where like numerals designate like components not described again in detail. The cooling system assembly 10B includes a three-dimensional heat exchanger 11 and the liquid cooling unit 12B. The three-dimensional heat exchanger 11 includes a vapor chamber 111 having a first thermally conductive plate 1111 and a second thermally conductive plate 1112. The liquid cooling unit 12B includes at least one coolant-carrying channel 120. In some embodiments, the at least one coolant-carrying channel 120 includes a third thermal transfer channel surface 121B and a fourth thermal transfer channel surface 125. The third thermal transfer channel surface 121B and the fourth thermal transfer channel surface 125 being substantially flat. The fourth thermal transfer channel surface 125 is opposite the third thermal transfer channel surface 121B. The third thermal transfer channel surface 121B is thermally coupled to the second thermal transfer surface 11132. In some embodiments, as an example, the substantially flat third thermal transfer channel surface 121B and the substantially flat fourth thermal transfer channel surface 125 are formed by stamping.

In some embodiments, the at least one coolant-carrying channel 120 includes at least one heat pipe. In some embodiments, the at least one coolant-carrying channel 120 includes an inlet 123, 123A, 123B and an outlet 124, 124A, 124B, whereby the second cooling fluid flows through the at least one coolant-carrying channel 120 via the inlet 123, 123A, 123B and the outlet 124, 124A, 124B. In some embodiments, the at least one coolant-carrying channel 120 is substantially round. In some embodiments, a shape of the at least one coolant-carrying channel 120 is a flat shoulder bottle-like shape, wherein the flat shoulder portion maximizes thermal coupling of the at least one coolant-carrying channel 120 to the outside surface of the second sub-chamber S2.

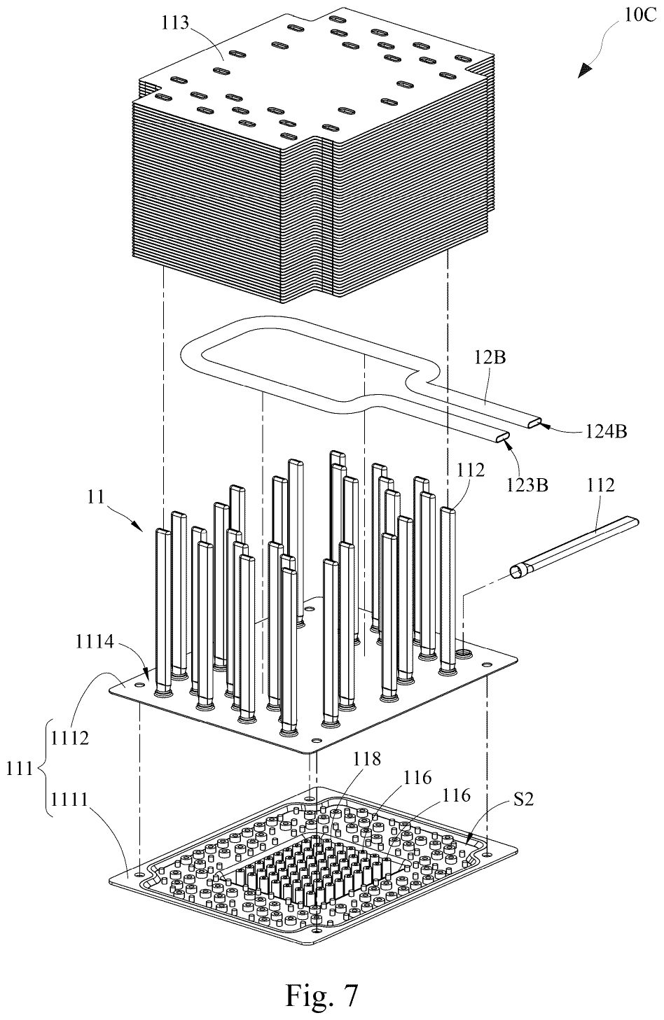

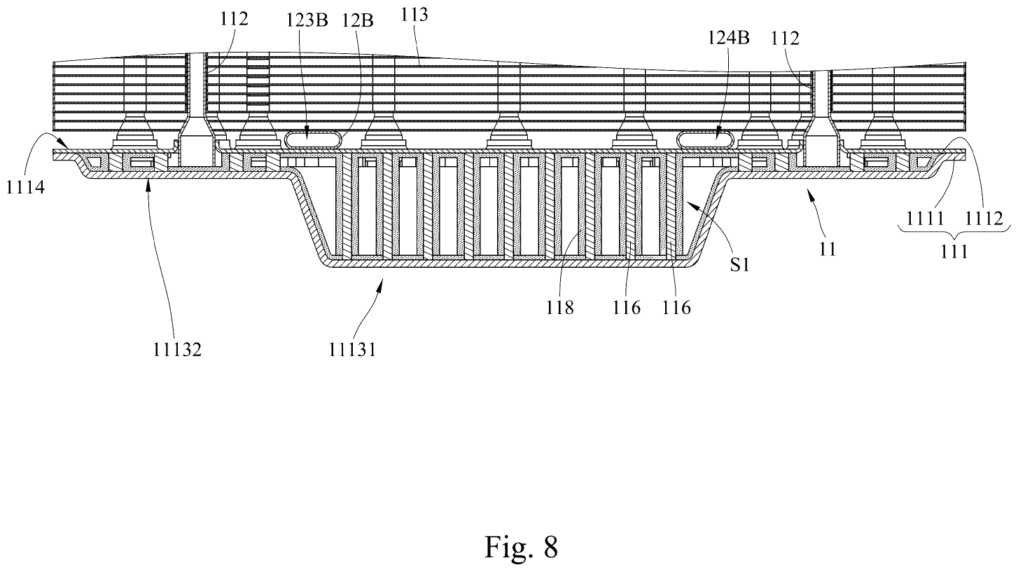

FIGS. 7 to 8 illustrate yet another alternative cooling system assembly 10C, in accordance with various embodiments of the present disclosure. The yet another alternative cooling system assembly 10C may be similar in some respects to the cooling system assembly 10 of FIGS. 1A to 2, and therefore may be best understood with reference thereto where like numerals designate like components not described again in detail. The cooling system assembly 10C includes a three-dimensional heat exchanger 11 and the liquid cooling unit 12. The three-dimensional heat exchanger 11 includes a vapor chamber 111 having a first thermally conductive plate 1111 and a second thermally conductive plate 1112. The liquid cooling unit 12B includes at least one coolant-carrying channel 120. In some embodiments, the second thermally conductive plate 1112 further includes a third thermal transfer surface 1114. The third thermal transfer surface 1114 is opposite the second sub-chamber S2. The at least one coolant-carrying channel 120 is thermally coupled to the third thermal transfer surface 1114. In some embodiments, the fourth thermal transfer channel surface 125 is thermally coupled to the third thermal transfer surface 1114.

In some embodiments, the cooling system assembly 10, 10A, 10B, 10C further includes a plurality of support pillars 115. The plurality of support pillars 115 includes a plurality of first support pillars 116 and a plurality of second support pillars 117. Each plurality of support pillars 115 is thermally coupled to the first thermally conductive plate 1111, 1111A and the second thermally conductive plate 1112. The plurality of first support pillars 116 is disposed in the first sub-chamber S1 and the plurality of second support pillars 117 is disposed in the second sub-chamber S2. The plurality of support pillars 115 are disposed parallel to one another

In some embodiments, the cooling system assembly 10, 10A, 10B, 10C further includes a plurality of capillary structures 114. The plurality of capillary structures 114 include a plurality of first capillary structures 118 and a plurality of second capillary structures 119. Each plurality of first capillary structures 118 is coupled to and surround each plurality of first support pillars 116. Each plurality of second capillary structures 119 is thermally coupled to and surround at least one plurality of second support pillars 117. In some embodiments, the plurality of capillary structures 114 consist of a sintered powder structure. In some embodiments, the cooling system assembly 10, 10A, 10B, 10C further includes capillary structures covering surfaces of the liquid-tight chamber S. In some embodiments, the capillary structures consist of a sintered powder structure. As an example, the capillary structures transport cooling fluid from an inner surface of the second thermally conductive plate 1112, the first thermally conductive plate 1111, and the plurality of heat pipes 112 back to the first sub-chamber S1 while keeping it separated from vapor traveling in an opposing direction.

Thermal conductivity of the three-dimensional heat exchangers 11, 11A of the embodiments is increased. The three-dimensional heat exchangers 11, 11A are configured for heat to be transported away therefrom. The coolant-carrying channels 120 are thermally coupled to the three-dimensional heat exchangers 11, 11A, absorbing heat therefrom and transporting the heat away via cooling lines (tubing or piping) to an air plenum or to an outside of a chassis or electronics system. The thermal transfer channel surfaces 121, 122, 121B, 125 and the disposition of the coolant-carrying channels 120 relative to the three-dimensional heat exchangers 11, 11A are varied for convenience and to maximize thermal coupling between the coolant-carrying channels 120 and the three-dimensional heat exchangers 11, 11A. Thus, greater thermal conductivity of the three-dimensional heat exchangers 11, 11A is provided, increasing the effectiveness and efficiency of the cooling system assemblies 10, 10A, 10B, 10C.

Therefore, embodiments disclosed herein are well adapted to attain the ends and advantages mentioned as well as those that are inherent therein. The particular embodiments disclosed above are illustrative only, as the embodiments disclosed may be modified and practiced in different but equivalent manners apparent to those of ordinary skill in the relevant art having the benefit of the teachings herein. Furthermore, no limitations are intended to the details of construction or design herein shown, other than as described in the claims below. It is therefore evident that the particular illustrative embodiments disclosed above may be altered, combined, or modified and all such variations are considered within the scope and spirit of the present disclosure. The embodiments illustratively disclosed herein suitably may be practiced in the absence of any element that is not specifically disclosed herein and/or any optional element disclosed herein. While compositions and methods are described in terms of “comprising,” “containing,” or “including” various components or steps, the compositions and methods can also “consist essentially of” or “consist of” the various components and steps. All numbers and ranges disclosed above may vary by some number. Whenever a numerical range with a lower limit and an upper limit is disclosed, any number and any included range falling within the range is specifically disclosed. In particular, every range of values (of the form, “from about a to about b,” or, equivalently, “from approximately a to b,” or, equivalently, “from approximately a-b”) disclosed herein is to be understood to set forth every number and range encompassed within the broader range of values. Also, the terms in the claims have their plain, ordinary meaning unless otherwise explicitly and clearly defined by the patentee. Moreover, the indefinite articles “a” or “an,” as used in the claims, are defined herein to mean one or more than one of the elements that it introduces.

1. A cooling system assembly, comprising:
a three-dimensional heat exchanger configured for phase-change of a first cooling fluid, including a vapor chamber comprising a first thermally conductive plate and a second thermally conductive plate, the first thermally conductive plate and the second thermally conductive plate together form a liquid-tight chamber, the liquid-tight chamber including a first sub-chamber and a second sub-chamber fluidly coupled to the first sub-chamber, second sub-chamber encircling the first sub-chamber, the first thermally conductive plate comprising a first thermal transfer surface, the first thermal transfer surface on one side and the first sub-chamber on an opposite side of the first thermal transfer surface, the first thermal transfer surface configured to thermally couple to at least one packaged integrated circuit; and
a liquid cooling unit configured to be flow through by a second cooling fluid, including at least one coolant-carrying channel, the at least one coolant-carrying channel coupled to an outside surface of the second sub-chamber,
wherein when the first thermal transfer surface is thermally coupled to the at least one packaged integrated circuit, the three-dimensional heat exchanger transports heat away from the at least one packaged integrated circuit and the liquid cooling unit transports heat away from the three-dimensional heat exchanger.

2. The cooling system assembly of claim 1, wherein the three-dimensional heat exchanger further comprises a fin stack and a plurality of heat pipes, each plurality of heat pipes respectively comprise an open end and a closed end, and the second thermally conductive plate comprises a plurality of thermal transfer through holes, each plurality of heat pipes respectively thermally coupled to the fin stack and the open end of each plurality of heat pipes respectively fluidly coupled to the vapor chamber through each plurality of thermal transfer through holes.

3. The cooling system assembly of claim 2, wherein the plurality of thermal transfer through holes is disposed fluidly coupled to the second sub-chamber.

4. The cooling system assembly of claim 2, wherein the plurality of heat pipes comprises twenty-eight plurality of heat pipes.

5. The cooling system assembly of claim 1, further comprising a plurality of support pillars, the plurality of support pillars including a plurality of first support pillars and a plurality of second support pillars, each plurality of support pillars thermally coupled to the first thermally conductive plate and the second thermally conductive plate, the plurality of first support pillars disposed in the first sub-chamber, the plurality of second support pillars disposed in the second sub-chamber.

6. The cooling system assembly of claim 5, further comprising a plurality of capillary structures, the plurality of capillary structures including a plurality of first capillary structures and a plurality of second capillary structures, each plurality of first capillary structures coupled to and surround each plurality of first support pillars, each plurality of second capillary structures thermally coupled to and surround at least one plurality of second support pillars.

7. The cooling system assembly of claim 6, wherein the plurality of capillary structures consist of a sintered powder structure.

8. The cooling system assembly of claim 1, wherein the first thermally conductive plate further comprises a second thermal transfer surface, the second thermal transfer surface encircling the first thermal transfer surface, the second thermal transfer surface opposite the second sub-chamber, the at least one coolant-carrying channel thermally coupled to the second thermal transfer surface.

9. The cooling system assembly of claim 8, wherein the at least one coolant-carrying channel comprises a first thermal transfer channel surface, the first thermal transfer channel surface being substantially flat, the first thermal transfer channel surface thermally coupled to the second thermal transfer surface.

10. The cooling system assembly of claim 9, wherein the first thermally conductive plate further comprises a channel groove, and the at least one coolant-carrying channel comprises a second thermal transfer channel surface, the second thermal transfer channel surface being substantially curved, the second thermal transfer channel surface thermally coupled to the channel groove, a plane of the second thermal transfer surface and the first thermal transfer channel surface is substantially flat.

11. The cooling system assembly of claim 8, wherein the at least one coolant-carrying channel comprises a third thermal transfer channel surface and a fourth thermal transfer channel surface, the third thermal transfer channel surface and the fourth thermal transfer channel surface being substantially flat, the fourth thermal transfer channel surface opposite the third thermal transfer channel surface, the third thermal transfer channel surface thermally coupled to the second thermal transfer surface.

12. The cooling system assembly of claim 1, wherein the second thermally conductive plate further comprises a third thermal transfer surface, the third thermal transfer surface opposite the second sub-chamber, the at least one coolant-carrying channel thermally coupled to the third thermal transfer surface.

13. The cooling system assembly of claim 12, wherein the at least one coolant-carrying channel comprises a third thermal transfer channel surface and a fourth thermal transfer channel surface, the third thermal transfer channel surface and the fourth thermal transfer channel surface being substantially flat, the fourth thermal transfer channel surface opposite the third thermal transfer channel surface, the fourth thermal transfer channel surface thermally coupled to the third thermal transfer surface.

14. The cooling system assembly of claim 1, further comprising capillary structures covering surfaces of the liquid-tight chamber.

15. The cooling system assembly of claim 14, wherein the capillary structures consist of a sintered powder structure.

16. The cooling system assembly of claim 1, wherein the at least one coolant-carrying channel comprises at least one heat pipe.

17. The cooling system assembly of claim 1, wherein the first sub-chamber includes a first thickness and the second sub-chamber includes a second thickness, the first thickness greater than the second thickness.

18. The cooling system assembly of claim 1, wherein the at least one coolant-carrying channel comprises an inlet and an outlet, whereby the second cooling fluid flows through the at least one coolant-carrying channel via the inlet and the outlet.

19. The cooling system assembly of claim 1, wherein a material of the vapor chamber is selected from a group consisting of an aluminum, aluminum-alloy, copper, and copper-alloy material.
